(19) United States
(12) Patent Application Publication
(10) Pub. No.: US 2013/0270756 A1
(43) Pub. Date: Oct. 17, 2013

(54) RETAINING SYSTEM FOR RETAINING AND HOLDING A WAFER

(71) Applicants: Markus Wimplinger, Ried im Innkreis (AT); Thomas Wagenleitner, Aurolzmunster (AT); Alexander Filbert, Florian am Inn (AT)

(72) Inventors: Markus Wimplinger, Ried im Innkreis (AT); Thomas Wagenleitner, Aurolzmunster (AT); Alexander Filbert, Florian am Inn (AT)

(73) Assignee: EV GROUP E. THALLNER GMBH, St. Florian Am Inn (AT)

(21) Appl. No.: 13/993,702

(22) PCT Filed: Dec. 14, 2010
(86) PCT No.: PCT/EP2010/007610

§ 371 Date: Jun. 13, 2013

(51) Int. Cl. H01L 21/683

(52) U.S. Cl. CPC H01L 21/6838
USPC 269/21

(57) ABSTRACT

This invention relates to a retaining system for retaining and holding a wafer for processing the wafer with a holding surface for placing the wafer on a support surface of the wafer and holding means for holding the wafer, whereby because of the holding means holding extremely thin wafers on the holding surface of the wafer, the smallest possible local distortions of the wafer are achieved.

This invention relates to a retaining system for retaining and holding a wafer for processing the wafer according one of Claims 1 or 2.

In the semiconductor industry, different types of retaining systems are used that are also referred as specimen holders or chucks. Based on the respective application process, there are various specimen holders that can be heated over the entire surface or locally, that can have different shapes and sizes, and that are based on various retaining principles. Because of continuously advancing miniaturization, in particular owing to increasingly larger wafer diameters with smaller wafer thicknesses, a requirement imposed on retaining systems is that the latter be designed as evenly as possible and with the least possible roughness.

The method most commonly used to fix a wafer to a retaining system consists in creating a vacuum in structures on the holding surface of the retaining system.

In particular in the bonding processes, the requirement exists that structural elements that are present on the wafer or the wafers have to be oriented exactly when connecting the wafer, namely along the entire contact surface of the two wafers. Since the structural elements have dimensions that are in the micrometer range and partially in the nanometer range, already slight deviations in the orientation position result in an improper connection between the structures.

The object of this invention is therefore to minimize as much as possible influences of the retaining system on the orientation or position of the structures of a wafer so that error sources for the orientation of a wafer or individual structures on the wafer are minimized.

This object is achieved with the features of Claims 1 and 2. Advantageous further developments of the invention are indicated in the subclaims. All combinations of at least two features indicated in the description, the claims and/or the drawings also fall within the scope of the invention. In the case of value ranges, values that lie within the above-mentioned limits are also to be disclosed as boundary values and can be claimed in any combination.

In this case, this invention is based on the finding that the particularly local holding forces that occur in holding extremely thin wafers on the holding surface of the wafer result in distortions of the wafer. The technical problem that a positional change of individual or several structures is produced on the wafer in an active state of the holding means for holding the wafer on the retaining system follows from the above. Such a positional change is minimized as much as possible by the measures according to the invention, whereby a first proposed solution consists in—in the case of a wafer thickness d of between a minimum of 50 μm or 100 μm and a maximum of 800 μm—limiting local distortions of the wafer along the support surface in the direction of the holding surface by corresponding construction of the holding means in such a way that the distortion compared to the inactive state of the holding means is less than 500 nm, in particular less than 250 nm, preferably less than 100 nm, more preferably less than 50 nm, and ideally less than 10 nm. A second proposed solution for achieving the above-mentioned effect consists in—for holding the wafer—a pressure differential between the support surface of the wafer and the print surface of the wafer that faces away from the support surface at the openings distributed along the holding surface to prevent a distortion, in particular a local distortion, of the wafer at the openings, in that the opening width D, in particular the diameter D, crosswise to the radial extension, has a mean inner width of less than 1,000 μm, advantageously less than 500 μm, in optimized embodiments less than 100 μm, in particular less than 50 μm, preferably less than 10 μm, and more preferably less than 1 μm. In this case, the pressure differential is a maximum 500 mbar, in particular a maximum 200 mbar, preferably a maximum 100 mbar, more preferably a maximum 50 mbar, and ideally a maximum 30 mbar. The distortions in the direction of the holding surface of the retaining system can be minimized especially by the measure that the opening width D is minimized crosswise to the radial extension of the holding surface or the support surface. In addition, it is advantageous according to the invention when the openings are distributed evenly over the holding surface so that as uniform as possible a holding force acts on the wafer along the holding surface in the active state of the holding means. Another optimization of the results is possible by the use of a reduced pressure differential since the forces that act on the wafer are thus minimized and thus distortions can be reduced.

Another proposed solution according to the invention consists in that the ratio of the wafer thickness d to particularly local distortions of the wafer along the support surface, produced by the holding means compared with the inactive state to the active state, is 1 to 100 greater, in particular 1 to 500 greater, preferably 1 to 1,000 greater, more preferably 1 to 5,000 greater, and ideally 1 to 10,000 greater.

An essential aspect of the above-mentioned proposed solution consists in that the holding surface of the retaining system is flat, so that local or global distortions of the wafer are not caused even by possible rough spots of the holding surface. To this end, the holding surface is ground planar with special tools and polished in such a way that even the waviness can be reduced to a minimum. Here, evenness values of more than 5 μm, in particular more than 3 μm, preferably more than 1 μm, and still more preferably more than 0.5 μm are desired. These values relate to the height difference between the highest and lowest points of the holding surface, whereby here only the surface that corresponds to the actual wafer diameter is rated.

Another measure according to the invention that is in accordance with an embodiment of the invention consists in that the openings provided for applying negative pressure, which are produced in particular by drilling and/or milling, are rounded on the edge between the opening and the holding surface or have a bezel. In the rounding configuration, the rounding has a rounding radius that is between one-fourth of the opening width D and the opening width D. The bezel extends from one inside wall of the opening along a support plane E over a distance of between one-fourth of the opening width D and the opening width D.

According to another advantageous embodiment of this invention, it is provided that the openings in the retaining system are arranged distributed in a uniform or even manner on the entire holding surface. In particular, the surface density of the openings is essentially constant over the entire holding surface of the retaining system. Surface density is defined as the sum of the surfaces F of any opening that is within the unit surface, a sum that is relative to a unit surface, in particular 1 mm² or 1 cm². The surface F of an opening is accordingly D²π/4. The surface density relative to a unit surface is: number of openings/4*(D²π)/unit surface. The surface density is non-dimensional.

Other advantages, features and details of the invention will become apparent from the description of preferred embodiments as well as based on the drawings. Here:

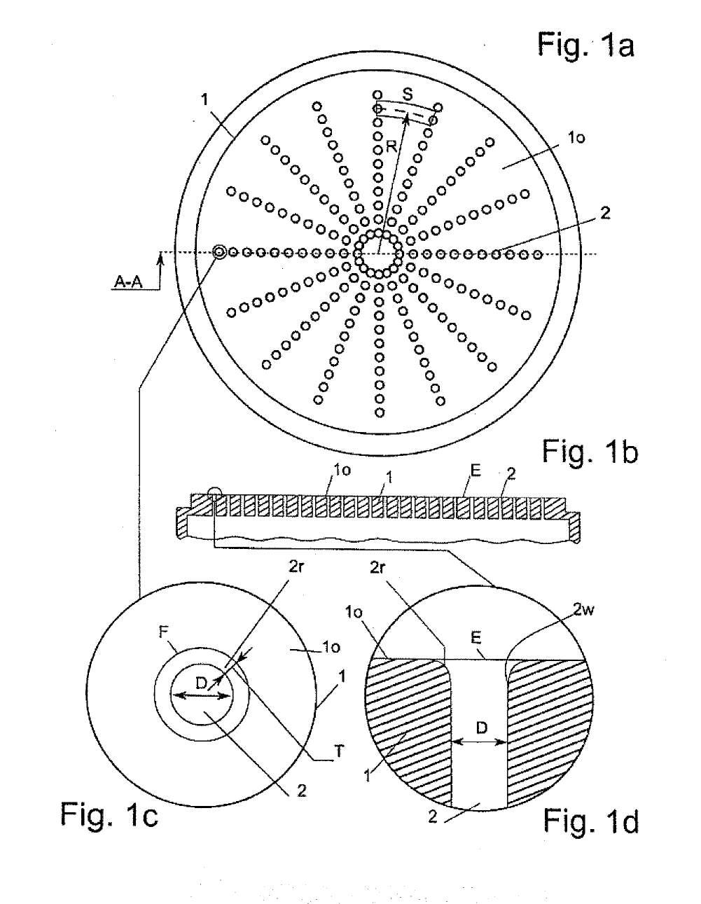

FIG. 1a shows a retaining system according to the invention in a top view,

FIG. 1b shows the retaining system according to FIG. 1a in a cutaway side view according to the line of intersection A-A according to FIG. 1a,

FIG. 1c shows an enlargement of an opening according to FIG. 1a,

FIG. 1d shows an enlargement of an opening according to FIG. 1b,

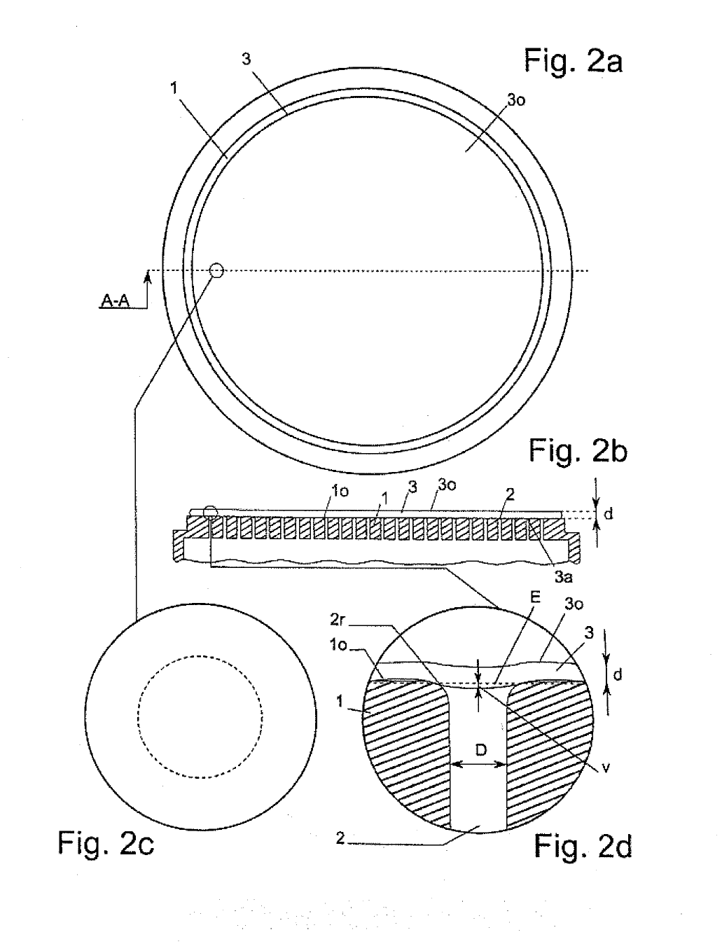

FIG. 2a shows a top view of the retaining system according to FIG. 1a with a wafer in the retained position,

FIG. 2b shows a cutaway side view of the retaining system according to FIG. 2a along the line of intersection A-A according to FIG. 2a,

FIG. 2c shows an enlargement of the top view according to FIG. 2a,

FIG. 2d shows an enlargement of the cross-sectional view according to FIG. 2b,

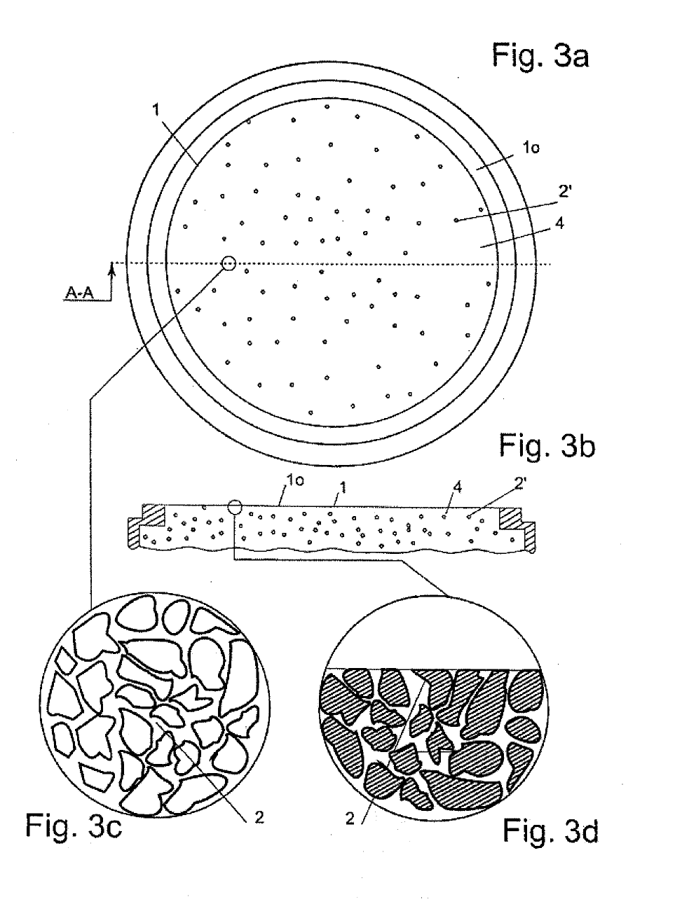

FIG. 3a shows a top view of an alternative embodiment of the retaining system according to the invention,

FIG. 3b shows a cutaway side view of the retaining system according to FIG. 3a along the line of intersection A-A of FIG. 3a,

FIG. 3c shows an enlargement of the retaining system according to FIG. 3a,

FIG. 3d shows an enlargement of the retaining system according to FIG. 3b, and

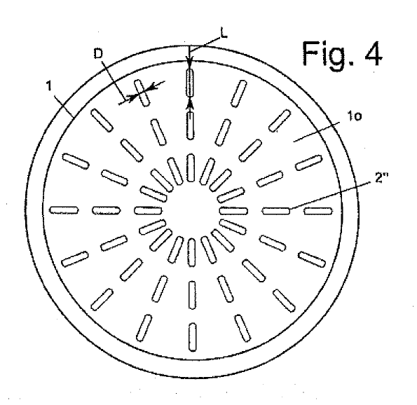

FIG. 4 shows a top view of another alternative embodiment of the retaining system according to the invention.

In the figures, components that are the same or that act the same are characterized with the same reference numbers.

FIGS. 1a and 1b show a retaining system 1 with a flat holding surface 1o for retaining and holding a wafer 3 that is shown in FIGS. 2a to 2d. The retaining of the wafer 3 is done by placing the wafer 3 on the holding surface 1o, for example by a robotic arm, not shown, that draws the wafer 3 from a stack of wafers or a cassette and lays it down on the holding surface 1o. For holding the wafer 3, holding means in the form of openings 2, which run through the retaining system 1, are provided on the holding surface 1o. On the side opposite the holding surface 10, the openings 2 can be subjected to negative pressure, for example by a vacuum system, not shown, which is included as part of the holding means.

The distribution of the openings 2 according to the embodiment shown in FIG. 1a is provided with a surface density that decreases with the increasing radius R of the holding surface 1o. This can be seen in the example of a circular ring cutaway S, which can be selected as a unit surface for determining the surface density. As soon as the radius R is reduced with the size of the circular ring cutaway S remaining the same, i.e., moves further inward to the center of the retaining system 1, the number of openings 2 detected in the circular ring cutaway S increases in such a way that the surface density increases in the direction of the center Z. The holding force acting on the wafer 3 correspondingly increases toward the center.

The number of openings 2 shown in FIG. 1a is purely diagrammatic and according to this invention, the number of openings 2 in a holding surface 1o for a standard 300 mm wafer is at least 50, in particular at least 100, and preferably at least 200. The surface density is at least 0.0005, in particular at least 0.001, and preferably at least 0.01, in each case relative to a unit surface, for example the circular ring cutaway S with a surface of 1 cm².

In the enlarged top view according to FIG. 1c, it can be seen that the opening 2 has a diameter D and thus a surface F, whereby according to the invention, the opening width D (here because of the circular cross-section: diameter), in particular the mean opening width D crosswise to the radial extension of the holding surface 10, is less than 1 mm, in particular less than 500 μm, preferably less than 100 μm, more preferably less than 1 μm, and ideally less than 100 nm.

According to one embodiment of the invention, which is shown in FIGS. 3a to 3d, the openings 2 as pores 2′ are provided with an open porosity along the entire holding surface 1o. In this case, the pores 2′ can be provided in particular in the form of a retaining insert 4 of the retaining system 1 that preferably consists of ceramic. In this case, the pores 2′ run through the retaining insert 4 so that a negative pressure can be applied at the side facing away from the holding surface lo also here analogously to the embodiment according to FIG. 1a to 1d or 2a to 2d.

According to FIGS. 1c and 1d, the openings 2 have a rounding 2r on the edge between each opening 2 and the holding surface 1o. The rounding radius r essentially corresponds to the radius of the opening 2, i.e., half the opening width D, whereby the openings 2 in the embodiment according to FIGS. 1a to 1d are designed as circular-cylindrical holes.

The holding surface 1o forms a support plane E. When placing the wafer 3 on the holding surface 10 with its support surface 3a in the support plane E, the wafer 3 is oriented namely as concentrically as possible to the center of the retaining system 1. After placing the wafer 3 on the retaining system 1 and in an inactive state of the holding means, the wafer 3 rests on the holding surface 1o only by its individual weight on the holding surface 1o. As soon as the holding means are switched into an active state, i.e., for example, a negative pressure is applied at the openings 2, the wafer 3 is drawn by suction to the openings 2 and thus held.

In the enlargement of the cross-section according to FIG. 2d, the effect of the negative pressure or the pressure differential between the atmospheric pressure on the print surface 3o of the wafer 3 and in the openings 2 can be seen. The wafer 3 is minimally distorted in the direction of the openings 2 because of the small wafer thickness d, namely by a distortion V, which corresponds to the maximum gap between the support plane E and the support surface 3a in the opening 2.

By the local distortions V that are carried out at each opening 2, a transverse distortion, i.e., along the support plane E, is created in the entire wafer 3, which is indicated diagrammatically by arrows in FIG. 2d. The transverse distortion, i.e., distortion along the support plane E, results in a movement of the wafer 3 relative to a wafer that is oriented or is to be oriented opposite, in particular a movement of structures, for example chips, arranged on the wafer 3 and/or the opposite wafer. By the rounding 2r, the deviation of the wafer is reduced in the areas lateral to the openings 2, and, moreover, damage of the wafer 3 is minimized or largely precluded on the edge.

These distortions represent a problem not only during bonding of two structured substrates, but they can also result in considerable problems when a structured substrate is bonded to a largely unstructured substrate. This is in particular the case when after the bonding, additional process steps that require a very exact orientation to the structured substrate are to be performed. In particular, lithography steps, in which additional layers of structures are to be oriented to structures already existing on the substrate, impose stringent requirements here. These requirements increase with decreasing structural size of the structures that are to be produced. Such an application occurs, for example, in the manufacturing of so-called back-lighted CMOS image sensors (English: “Backside Illuminated CMOS Image Sensor”). In this case, a first wafer with the already structured surface is bonded to a support wafer, particularly one that is largely unstructured. After a permanent bond connection is formed, the majority of the wafer material of the structured wafer is removed in such a way that the structured surface, in particular the light-sensitive points, are accessible from the rear. In connection to this, this surface has to be subjected to additional process steps, in particular lithography, to apply, for example, color filters that are necessary for the function of the image sensor. Distortions of these structures adversely affect the orientation accuracies that can be achieved with this lithography step. For today's generations of image sensors with a pixel size of, for example, 1.75 μm or 1.1 μm, the distortions that are permissible for an illumination field (up to 26×32 mm) of a Step & Repeat illumination system are approximately 100 nm, or better yet 70 or 50 nm.

In this document, pre-bonding refers to bonding connections that after the pre-bonding step has taken place still allow a separation of substrates, in particular the wafers, without irreparable damage of the surfaces. These bond connections can therefore also be referred to as reversible bonds. This separation is usually possible based on the fact that the bonding strength/the adhesion between the surfaces is still low enough. This separation is usually possible until the bond connection becomes permanent, i.e., can no longer be separated (becomes non-reversible). This can be achieved in particular by a certain time span elapsing and/or the action on the wafer from outside by physical parameters and/or energy. Here, in particular the pressing-together of the wafer by means of a compressive force or heating the wafer to a certain temperature or exposing the wafer to microwave irradiation are suitable. An example of such a pre-bond connection would be a connection between a wafer surface with a thermally produced oxide and a wafer surface with native oxide, whereby here at room temperature, it results in van der Waals connections between the surfaces. Such bond connections can be converted into permanent bond connections by temperature treatment. Such pre-bonding compounds advantageously also allow an inspection of the bonding result before the forming of the permanent bond connection. In the case of deficiencies noted in this inspection, the substrates can still be separated once again and rejoined.

In the embodiments shown in FIGS. 3a to 3d, the retaining system 1 has a porous support part as a retaining insert 4, whereby the porous support part has an open porosity in the entire support part. The retaining insert is fixed in the retaining system 1.

Corresponding to the openings 2 of the embodiment according to FIGS. 1 and 2, the porous support part has pores 2′ whose structural parameter is the mean pore diameter. The pore diameter is less than 1 mm, in particular less than 100 μm, preferably less than 1 μm, more preferably less than 100 nm, and ideally less than 10 nm. For the sake of clarity, the pores 2′ or the grain size is/are shown in heavily schematized form in FIG. 3. The porous support part is preferably a ceramic component. To achieve as constant a surface density of the pores 2 as possible, the ceramic is produced by sintering.

In FIG. 4, one embodiment is the retaining system 1 with longitudinal openings 2″ extending lengthwise in the radial direction of the retaining system 1. The ratio of the opening width D to the length L of the openings 2″ is between 1 to 2 and 1 to 10, in particular between 1 to 3 and 1 to 6, and preferably between 1 to 4 and 1 to 5. Despite the thin support surface and avoidance of the especially harmful radial distortions, the longitudinal configuration prevents the openings 2″ from being clogged by particles or the like as a result of the distortions V in the direction of the holding surface 1o.

### LIST OF REFERENCE SYMBOLS

1 Retaining system

1o Holding surface

2, 2″ Openings

2r Rounding

2′ Pores

2w Inside wall

3 Wafer

3a Print surface

3o Support surface

4 Retaining insert

d Wafer thickness

D Opening width

E Support plane

F Surface

L Length

r Rounding radius

R Radius

S Circular ring cutaway

V Distortion

1-5. (canceled)

6. Retaining system for retaining and holding a wafer for processing the wafer, said retaining system comprising:
a holding surface for receiving the wafer, wherein a support surface of the wafer is placed on the holding surface, the holding surface formed on a porous support part of the retaining system, wherein the porous support part is formed as a retaining insert, and
holding means for holding the wafer, whereby the holding means can be switched between an active state and an inactive state, the holding means having pores in the porous support part with an open porosity in the entire porous support part, wherein with said wafer having a thickness d of between 50 μm and 800 μm, the holding means in the active state causes local distortions of the wafer along the support surface in the direction of the holding surface of less than 500 nm.

7. Retaining system according to claim 6, wherein said pores have a mean pore diameter of less than 1 μm.

8. Retaining system according to claim 7, wherein said pores have a mean pore diameter of less than 100 nm.

9. Retaining system according to claim 6, wherein surface density of the pores on the holding surface is essentially constant over the entire holding surface.

10. Retaining system according to claim 9, wherein the porous support part is formed as a ceramic component.

11. Retaining system according to claim 10, wherein said porous support part is formed by sintering.

12. Use of a retaining system for retaining and holding a wafer for processing the wafer, said retaining system comprising:
a holding surface for receiving the wafer, wherein a support surface of the wafer is placed on the holding surface, the holding surface formed on a porous support part of the retaining system, wherein the porous support part is formed as a retaining insert, and
holding means for holding the wafer, whereby the holding means can be switched between an active state and an inactive state, the holding means having pores in the porous support part with an open porosity in the entire porous support part, wherein with said wafer having a thickness d of between 50 μm and 800 μm, the holding means in the active state causes local distortions of the wafer along the support surface in the direction of the holding surface of less than 500 nm,
wherein said retaining system is used for bonded wafers that can be reworked or are to be reworked.
